(19) United States
(12) Patent Application Publication
(10) Pub. No.: US 2023/0100761 A1
(43) Pub. Date: Mar. 30, 2023

(54) THERMAL RUNAWAY PIN-POINT HEATING TEST

(71) Applicant: Lenovo (United States) Inc., Morrisville, NC (US)

(72) Inventors: Bouziane Yebka, Apex, NC (US); Tin-Lup Wong, Chapel Hill, NC (US); Philip John Jakes, Durham, NC (US)

(21) Appl. No.: 17/486,133

(22) Filed: Sep. 27, 2021

(51) Int. Cl. H01M 10/42; H01M 10/48; G01R 31/28

(52) U.S. Cl. CPC H01M 10/4285; H01M 10/48; G01R 31/2875

(57) ABSTRACT

A method and apparatus permit the testing of electrochemical cells. The apparatus includes a heat source, a chamber, and a diffuser coupling the heat source to the chamber. The heat source applies heat via the diffuser to a pin-point section of the electrochemical cell. This application of heat causes a thermal runaway condition due to a localized internal short circuit in the electrochemical cell. It is then determined whether the electrochemical cell has vented, ruptured, or exploded in response to the application of the heat source to the thermal runaway pin-point section of the electrochemical cell.

### TECHNICAL FIELD

Embodiments described herein generally relate to the testing of electrochemical cells/batteries, and in an embodiment, but not by way of limitation, a thermal runaway pin-point heating test for electrochemical cells or batteries by emulating an internal short circuit without affecting the integrity of the electrochemical cells or batteries.

### BACKGROUND

There are four types of critical internal short circuits that can occur in certain electrochemical cells. These types are a current collectors (positive & negative) short circuit, a negative current collector-cathode short circuit, a positive current collector-anode short circuit, and an anode-cathode short circuit. Out of these types, the greatest risk for cell failure occurs with the current collectors (positive & negative) short circuit. Regardless of the type of failure, the failure results from thermal runaway. Thermal runaway can take place if the cell is abused or not properly designed, and a catastrophe can occur such as a rupture of the cell or an explosion. There are several factors that lead to such internal short circuits such as material flaws, manufacturing flaws, contamination, dendrite growth, metal plating, external abuse, exposure to extreme temperatures, etc.

An example of a material flaw is a situation when a separator in an electrochemical cell has become damaged, compressed, or perforated. This damage, compression, or perforation may lead to a short between an anode and a cathode depending on the separator design and material, This results in a single point of contact between the anode and the cathode. Degradation of the separator may occur if subjected to high temperatures, and/or the degradation may occur because the materials were incorrectly specified.

Several tests currently exist that can determine if a particular electrochemical cell design has an unacceptable chance of leading to an internal short circuit and a subsequent thermal runaway condition and failure. However, these tests have shortcomings.

A first test is referred to as the nail penetration test. In the nail penetration test, a nail is driven into the electrochemical cell in an attempt to create an internal short circuit. However, the test is not consistent because there are many variables in the test. These variables include the speed at which the nail penetrates the electrochemical cell, the sharpness or dullness of the nail, and the conductivity of the nail. Also, the process by which a commercial electrochemical cell in the field progresses to thermal runaway due to an internal short circuit involves very different physical processes than those generated by the nail penetration test.

The nail penetration test is therefore not a useful test for the type of internal short circuits that develop over time in the field. The thermal runaway associated with nail penetration takes place within about 200-500 milliseconds, not over time as in the field. Nail penetration tests consequently produce variable results, and do not reflect the failure conditions by which internal short circuits result in thermal runaway. Perhaps most critically, the nail penetration test does not create a single point of contact between the anode and the cathode.

There are also several heating tests that can test the design of an electrochemical cell's susceptibility to internal short circuits and thermal runaway conditions. For example, there are heating tapes, thermal chambers, sand baths, ceramic heaters, infrared emissions (focused), photonic emissions (laser), and direct flames. However, these current heat tests do not in any way emulate any of the types of internal short circuits that occur in the field. That is, once again, and perhaps most critically, these current heat tests do not create an electrical short with a single point of contact.

An existing test for electrochemical cells that does create an internal short circuit is the force internal short circuit (FISC) test. The MSC test is designed to emulate an internal short circuit where a single point of contact occurs between an anode and a cathode. The FISC test may detect problems with the electrochemical cell that result from material flaws, manufacturing flaws, contamination, dendrite growth, and lithium plating. The FISC test does allow a single point of contact between an anode and a cathode, without introducing other factors causing inaccuracy, doubt and false results. However, a shortcoming of the FISC test is that it does not evaluate the vent performance and electrochemical cell can structural integrity under thermal runaway conditions.

Additionally, the FISC test requires that the electrochemical cell be fully charged. It further requires the disassembly of a cell and the placement of a metal particle (a special calibrated metal particle placed in one or two locations based on the design of the cell) in the cell. The FISC test also must be conducted in special environment with special non-conductive tools. The FISC test must be completed in less than 30 minutes in order to prevent electrolyte evaporation. The FISC test further requires that the cell be placed in sealed bag and then conditioned in a chamber.

Another existing test, the NREL/NASA (National Renewable Energy Laboratory; National Aeronautics and Space Administration) internal short circuit instigator, also creates a single point of contact between an anode and a cathode on demand. Moreover, the NREL/NASA test does not crush the cell, does not penetrate the cell, does not bend, warp, or deform the cell, and does not compromise the integrity of the cell. Additionally, the NREL/NASA test can be created by the cell manufacturer, can be activated independently at any state of charge, is suitable for cylindrical, prismatic and pouch cell designs, and poses minimal risk in the test laboratory (handling and activation). However, the NREL/NASA test is somewhat artificial since the battery cell has to be manufactured with elements that are specifically needed for the test, for example, a copper pad, a separator with the copper puck, a wax phase change material, and an aluminum pad. Additionally, like with the FISC test, the NREL/NASA test does not evaluate the vent performance, and the electrochemical cell can structure integrity under thermal runaway conditions.

To ensure proper testing of electrochemical cells' reliability, their safety mechanisms, and functions under thermal runaway condition, only test methods that emulate a real-world single point of contact internal short circuit should be considered. As noted above, the FISC and NREL/NASA tests can create a single point of contact internal short circuit, but these tests have shortcomings. Test methods that compromise the integrity of the electrochemical cell (e.g., crushing, penetration, deformation, and heating) are not representative of an internal electrically or electrochemically induced short circuit failure of any kind.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings.

FIGS. 1A and 1B are a block diagram illustrating operations and features of an electrochemical cell thermal runaway pin-point heating test system.

FIG. 2 illustrates an embodiment of an electrochemical cell thermal runaway pin-point heating system.

FIG. 3 illustrates another embodiment of an electrochemical cell thermal runaway pin-point heating test system.

FIG. 4 illustrates differences in heating area of an electrochemical cell using an embodiment disclosed herein and a prior normal heating method.

### DETAILED DESCRIPTION

To overcome the shortcomings of existing electrochemical cell safety tests, what is needed is a test that provides qualitative and quantitative means to measure the chances of an electrochemical cell failure under thermal runaway conditions, and a test that can evaluate the vent performance and can structure integrity of the electrochemical cell under thermal runaway conditions. While thermal runaway and venting are expected, can rupture should not occur. If can rupture occurs, there is a problem with the design and/or materials of the cell. An embodiment of the present disclosure addresses these shortcomings of the existing electrochemical cell tests and satisfies these needs.

An embodiment dynamically can step through all the protection mechanisms that are built into the cell. Prior methods cannot do this. For example, the center pipe for gas discharge, pressure relief safety valve, and other features of a cell can be observed during the test. That is, failure of these mechanisms which resulted in metal can disintegration, ejection of jelly roll, and casing explosion can actually be observed in the embodiment of the thermal runaway pin-point heating test. The embodiment finds defects in electrochemical cell design that could cause safety concerns for a user, shows that the safety mechanism of a cell (e.g., a current interrupt device (CID)) works as intended under thermal runaway conditions, and creates an internal short circuit without affecting the cell integrity like tests that puncture, deform, bend, and/or crush the cell.

There are several advantages to the thermal runaway pin-point heating test. There is precise temperature control. The test is applied directly to a final cell product without any extra preparation like in some existing tests. The test allows for real time data collection and visual observation. The test provides quantitative measurements, and it is flexible, simple, safe, reliable, fast, inexpensive, and reproducible.

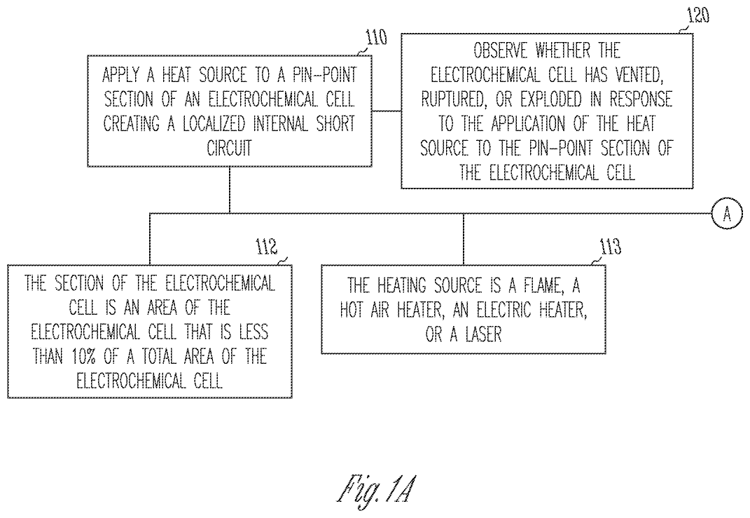

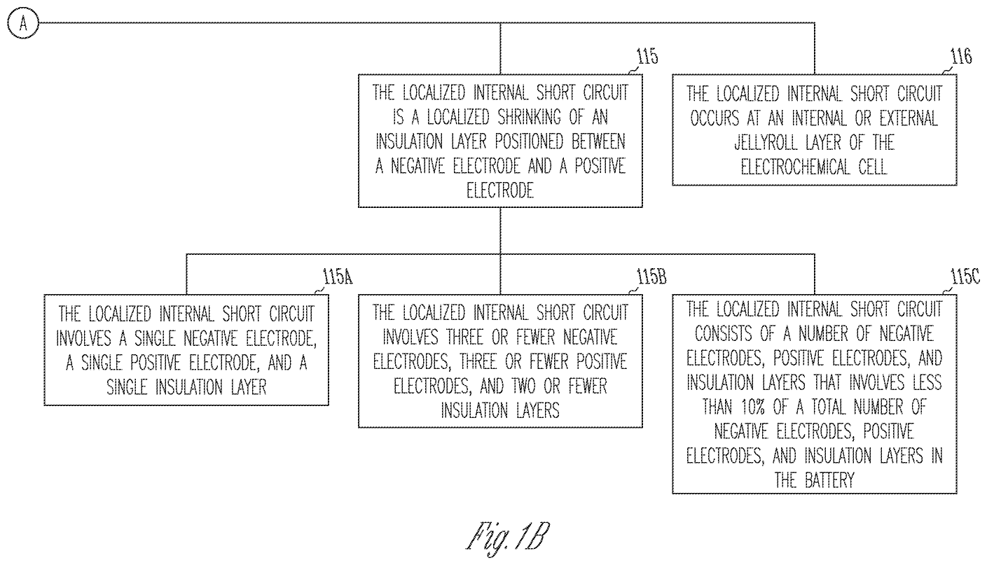

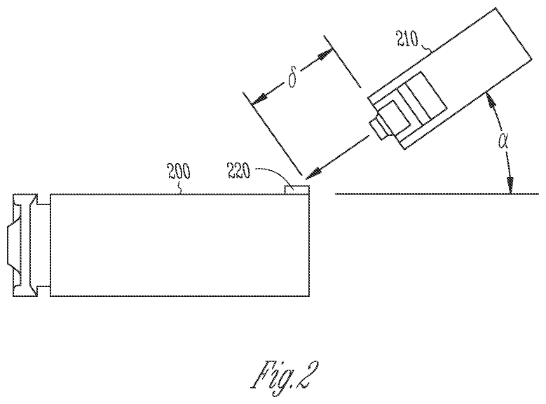

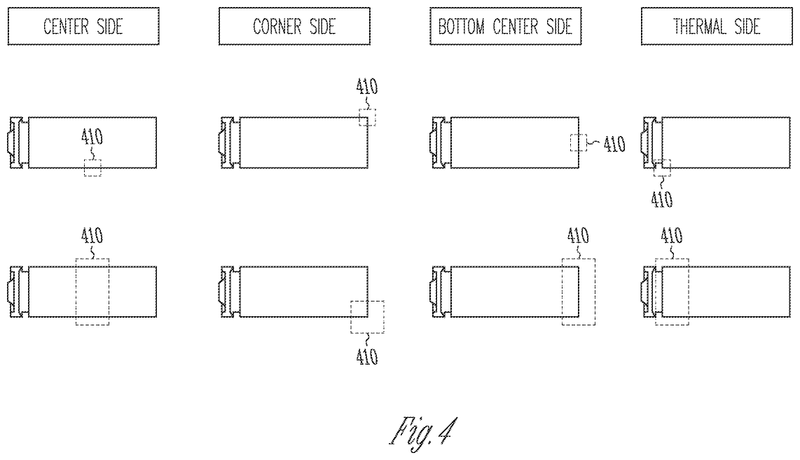

FIGS. 1A and 1B illustrate the steps, operations, and features of the thermal runaway pin-point heating test for an electrochemical cell. At 110, a heat source is applied to a section of the electrochemical cell. One such electrochemical cell that the test can be used on is a Lithium-ion battery. These electrochemical cells can be used in many products such as computer laptops and electric vehicles. In an embodiment, as illustrated at 112, the section of the electrochemical cell comprises an area of the electrochemical cell that is less than 1% of a total area of the electrochemical cell. In other embodiments, the heated section can be less than or greater than 1% of the total area of the electrochemical cell. The differences in total area of heating of the cell for an embodiment of this disclosure and a prior normal heating method are illustrated in FIG. 4. FIG. 4 illustrates four areas of heating (center side, corner side, bottom center side, and terminal side), and the differences in the heating areas 410. This heating of the electrochemical cell causes a thermal runaway condition due to a localized internal short circuit in the electrochemical cell. FIG. 2 illustrates a heat source 210 that is applied to a limited, concentrated, or pin-point section of the electrochemical cell 200. As illustrated in FIG. 2, in this particular embodiment, the heating source is directed at a particular section or point 220 of the electrochemical cell 200, and the heating source is placed, without physical contact, in close proximity to the electrochemical cell 200 at a specific angle from the casing of the electrochemical cell. The heating source can be anything such as a flame, a hot air heater, an electric heater, and/or a laser (113).

As indicated at 115, the localized internal short circuit is caused by a localized shrinking of the separator/insulation layer 250 that is positioned between the negative electrode 240 and the positive electrode 260. In an embodiment, the localized internal short circuit involves a single negative electrode, a single positive electrode, and a single insulation layer (115A). In another embodiment, the localized internal short circuit involves three or fewer negative electrodes, three or fewer positive electrodes, and two or fewer insulation layers (115B). In yet another embodiment, the localized internal short circuit consists of a number of negative electrodes, positive electrodes, and insulation layers that involves less than 1% of a total number of negative electrodes, positive electrodes, and insulation layers in the battery (115C). As indicated at 116, a jellyroll internal short circuit can be caused by an anode crimping past a shrunken separator and causing a single point of failure contact with a cathode.

After the heat source is directed at the electrochemical cell in operation 110, then at 120, it is then observed whether the electrochemical cell has vented, ruptured, or exploded in response to the application of the heat source to the section of the electrochemical cell.

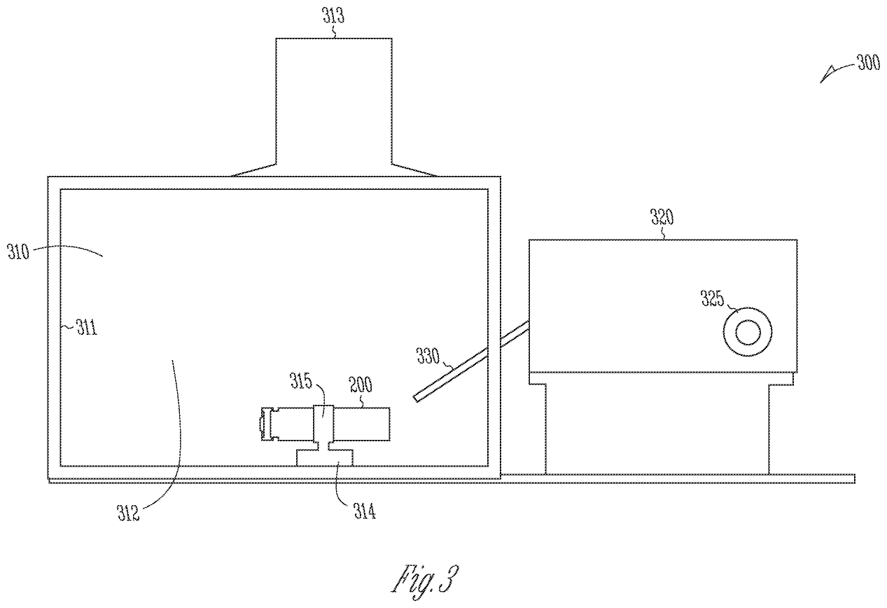

In an embodiment, the system 300 of FIG. 3 can be used to apply the heat source to the electrochemical cell and to make the observation and determination of whether the electrochemical cell has vented, ruptured, or exploded. The system 300 includes a chamber 310, a hot air generator 320, and a diffuser 330 coupling the hot air generator 320 to the chamber 310. The hot air generator has a temperature controller 325. The chamber 310 is manufactured out of metal walls 311 and an explosion proof window 312, and further includes an exhaust vent 313. Within the chamber 310 is a metal platform 314, and a sample holder 315. In an embodiment, the sample holder 315 includes one or more thermocouples. The sample holder 315 maintains the electrochemical cell in place, and the thermocouples provide an accurate temperature of the sample electrochemical cell. The electrochemical cell to be tested is positioned in the chamber 310. The operations of FIG. 1A and are then carried out on the electrochemical cell being tested. That is, the hot air generator applies heat to a pin-point section of the electrochemical cell via the diffuser. As noted, this causes a thermal runaway condition due to a localized internal short circuit in the electrochemical cell. The electrochemical cell is then observed through the explosion proof window, and it is determined whether the electrochemical cell has vented, ruptured, or exploded in response to the application of the heat source to the section of the electrochemical cell.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document. the term “or” is used to refer to a nonexclusive or, such that “A or B” includes “A but not B,” “B but not A.” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third.” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

1. A process to test an electrochemical cell comprising:
applying a heat source to a section of the electrochemical cell, thereby causing a thermal runaway condition due to a localized internal short circuit in the electrochemical cell; and
determining whether the electrochemical cell has vented, ruptured, or exploded in response to the application of the heat source to the section of the electrochemical cell.

2. The process of claim 1, wherein the localized internal short circuit comprises a single point of contact between a positive electrode and a negative electrode.

3. The process of claim 1, wherein the localized internal short circuit occurs at an internal or external jellyroll layer of the electrochemical cell.

4. The process of claim 1, wherein the section of the electrochemical cell comprises an area of the electrochemical cell that is less than 1% of a total area of the electrochemical cell.

5. The process of claim 1 wherein the section comprises a pin-point section.

6. The process of claim 1, wherein the localized internal short circuit comprises a single negative electrode, a single positive electrode, and a single insulation layer.

7. The process of claim 1, wherein the localized internal short circuit comprises three or fewer negative electrodes, three or fewer positive electrodes, and two or fewer insulation layers.

8. The process of claim 1, wherein the localized internal short circuit comprises a number of negative electrodes, positive electrodes, and insulation layers that comprises less than 1% of a total number of negative electrodes, positive electrodes, and insulation layers in the battery.

9. The process of claim 1, wherein the localized internal short circuit comprises a localized shrinking of an insulation layer positioned between a negative electrode and a positive electrode.

10. The process of claim 1, wherein the heat source comprises one or of a flame, a hot air heater, an electric heater, and a laser.

11. A system comprising:
a heat source:
a chamber; and
a diffuser coupling the heat source to the chamber;
wherein the system is operable for testing an electrochemical cell comprising:
positioning the electrochemical cell in the chamber;
applying the heat source via the diffuser to a section of the electrochemical cell, thereby causing a thermal runaway condition due to a localized internal short circuit in the electrochemical cell; and
determining whether the electrochemical cell has vented, ruptured, or exploded in response to the application of the heat source to the section of the electrochemical cell.

12. The system of claim 11, comprising an apparatus to receive, the electrochemical cell, the apparatus comprising a thermocouple.

13. The system of claim 11, wherein the chamber comprises an explosion proof window.

14. The system of claim 11, wherein the section of the electrochemical cell comprises an area of the electrochemical cell that is less than 1% of a total area of the electrochemical cell.

15. The system of claim 11, wherein the section comprises a pin point section.

16. The system of claim 11, wherein the localized internal short circuit comprises a single negative electrode, a single positive electrode, and a single insulation layer.

17. The system of claim 11, wherein the localized internal short circuit comprises three or fewer negative electrodes, three or fewer positive electrodes, and two or fewer insulation layers.

18. The system of claim 11, wherein the localized internal short circuit comprises a number of negative electrodes, positive electrodes, and insulation layers that comprises less than 1% of a total number of negative electrodes, positive electrodes, and insulation layers in the electrochemical cell.

19. The system of claim 11, wherein the localized internal short circuit comprises a localized shrinking of an insulation layer positioned between a negative electrode and a positive electrode.

20. The system of claim 11, wherein the heat source comprises one or more of a flame, a hot air heater, an electric heater, and a laser.
